(19) United States
(12) Patent Application Publication
(10) Pub. No.: US 2008/0278249 A1
(43) Pub. Date: Nov. 13, 2008

(54) LC-TYPE VCO

(76) Inventor: Sami Hyvonen, Beaverton, OR (US)

Correspondence Address: INTEL CORPORATION;c/o INTELLEVATE, LLC, P.O. BOX 52050, MINNEAPOLIS, MN, 55402, US

(21) Appl. No.: 11/746,403

(22) Filed: May 9, 2007

(51) Int. Cl. H03B 7/06; H03J 3/20

(52) U.S. Cl. 331/117 R

(57) ABSTRACT

Disclosed herein are embodiments of an LC-type VCO with multiple operational frequency bands having reasonably similar frequency vs. control signal slopes.

### BACKGROUND

The present invention relates generally to voltage controlled oscillators (VCOs) and in particular, to LC-type VCOs.

Voltage controlled oscillators (VCOs) are used for a wide variety of applications including but not limited to phase locked loops (PLLs), delay locked loops (DLLs) and mixer circuits, to mention just a few. There are different types of VCOs including ring oscillator and LC (inductor-capacitor) types. LC VCOs typically use one or more amplifiers coupled to a tank circuit formed from one or more inductors and capacitors. usually, some of the capacitors and/or inductors are controllably variable (e.g., based on an applied control voltage) so that the LC VCO output frequency can be varied in response to the control voltage.

FIG. 1 shows a conventional LC-type VCO. It generally comprises a differential amplifier, formed from P-type transistors P1, P2, and current source I1, and a tank circuit formed from selectably engageable fixed capacitors C1-C6, variable capacitor (or varactor) VC1, and inductors L1, L2. The fixed capacitors are grouped into three separately engageable sets: C1-C2, C3-C4, and C5-6. Different combinations of these capacitor groups can be selected resulting in eight different operating frequency bands. The variable capacitor VC1 is coupled to a control voltage V_{ctrl} (e.g., from a charge pump or loop filter in a PLL), which controls the output frequency by controlling the capacitance of the variable capacitor VC1. The VCO generates a differential output signal at nodes Vₒᵤₜ, V#ₒᵤₜ whose frequency is based on the selected capacitor groups and the control voltage (V_{ctrl}) level.

Unfortunately, an undesirable aspect of this circuit is that the slopes (K_{VCO}) of the output frequency vs. control voltage curve is different for each frequency band. Accordingly, an improved solution is desired.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a schematic diagram of a conventional LC type VCO.

FIG. 2 is a schematic diagram of an LC-type VCO in accordance with some embodiments.

FIG. 3 is a schematic diagram of a selectably engageable variable capacitor in accordance with some embodiments.

FIG. 4 is a block diagram of a computer system with an LC VCO in accordance with some embodiments.

FIG. 5 is a schematic diagram of an LC-type VCO in accordance with some other embodiments.

### DETAILED DESCRIPTION

At least for purposes of this disclosure, VCO gain (K_{VCO}) is defined as oscillation frequency change for a given control signal (e.g., control voltage) change. This can be represented as:

$${K}_{VCO} = \frac{d {ω}_{o} ( {V}_{ctrl} )}{d {V}_{ctrl}} \qquad ( Eq . 1 )$$

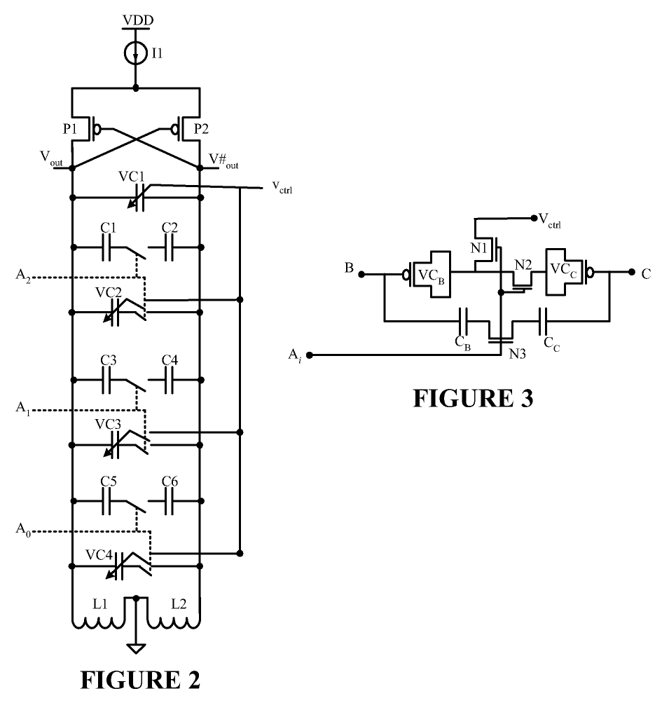

For an LC-type VCO (such as is shown in FIG. 2 or FIG. 5, discussed below), K_{vco} can be derived from the tank resonant frequency:

$${K}_{VCO} = \frac{d ω ( {V}_{ctrl} )}{d {V}_{ctrl}} = \frac{d}{d {V}_{ctrl}} [ \frac{1}{\sqrt{LC ( {V}_{ctrl} )}} ] \qquad ( Eq . 2 )$$

Where C(V_{ctrl})=C_{fixed}+Cᵥₐᵣ(V_{ctrl}) is the total tank capacitance. (In this type of LC VCO, the fixed and variable capacitors are in parallel thereby resulting in their net capacitance being additive. It should be appreciated, however, that other inductor-capacitor configurations could be implemented and are within the scope of the invention.) Accordingly, the overall tank capacitance is a function of V_{ctrl} because the variable capacitance depends on V_{ctrl}. K_{VCO} can be expressed as:

Taking the derivative yields an equation for K_{vco}:

$${K}_{VCO} = \frac{1}{\sqrt{L}} \cdot \frac{d}{d {V}_{ctrl}} [ \frac{1}{\sqrt{C ( {V}_{ctrl} )}} ] = - \frac{1}{2 \sqrt{L}} \cdot \frac{1}{{[ C ( {V}_{ctrl} ) ]}^{3 / 2}} \cdot \frac{d C ( {V}_{ctrl} )}{d {V}_{ctrl}} \\ \begin{matrix}because \text{:} & ω ( {V}_{ctrl} ) = \frac{1}{\sqrt{LC ( {V}_{ctrl} )}} ,\end{matrix} \qquad ( eq . 3 )$$

the Kvco equation can be rearranged to get:

$${K}_{VCO , rad} = - \frac{L \cdot {{ω}_{O} ( {V}_{ctrl} )}^{3}}{2} \cdot \frac{d {C}_{var} ( {V}_{ctrl} )}{d {V}_{ctrl}} \qquad ( Eq . 4 )$$

It has been determined that in order to attain an LC-type VCO with a wide-band capability with a constant (or reasonably approaching constant) Kvco for the different frequency bands, the change in frequency should be compensated by either changing inductance (which is typically impractical) or by changing the variable capacitance slope. Different embodiments disclosed herein involve changing the varactor slope, e.g., by appropriately changing the variable capacitance in conjunction with changes in the fixed capacitance, when moving between frequency bands. By adjusting the variable capacitor sizes (and, consequently, the slope of the combined tank varactor) to accommodate the change in frequency (i.e., change in total tank capacitance), K_{vco} can be made to be reasonably consistent over the different frequency bands.

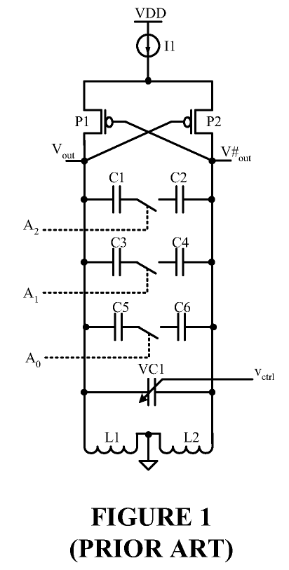

FIG. 2 shows an LC-type VCO with compensated variable capacitance in accordance with some embodiments. The depicted VCO is similar to the VCO circuit of FIG. 1, except that each fixed capacitor group additionally has an associated variable capacitor that is selectably engageable with an associated fixed capacitor group. The depicted VCO has a variable capacitor VC1 that is always engaged, along with three additional variable capacitors VC2-VC4, each associated with a different fixed capacitor group. In particular, the VCO has a first capacitor group formed from fixed capacitors C1, C2, and variable capacitor VC2; it has a second capacitor group formed from fixed capacitors C3, C4, and variable capacitor VC3; and it has a third capacitor group formed from fixed capacitors C5, C6, and variable capacitor VC4.

In accordance with some embodiments, the total fixed capacitance of the first group is 2 times larger than that of the second group, which is two times larger than that of the third group. In other words, the first group is the most significant group, and the third group is the least significant group, with the groups being binary weighted relative to each other. With such a configuration, eight separate, equally spaced apart frequency bands are available, depending on the values of selection control inputs A₀, A₁, and A₂. For example, in some embodiments, C5 and C6 are each 0.2 pF, resulting in the third group fixed capacitance being 0.1 pF. C3 and C4 are each 0.4 pF, resulting in the second group capacitance being 0.2 pF; and C1 and C2 are 0.8 pF, resulting in the first group capacitance being at 0.4 pF. The inductors L1, L2 are each 0.5 nH, and the variable capacitors are each at capacitor ranges that result in a near-constant KVCO for the eight different frequency bands. In accordance with Equation 3 (above), the variable capacitors are chosen so that the product of 1/[C(V_{ctrl})^{3/2}] and dC(V_{ctrl})/dV_{ctrl} is maintained substantially constant over the different frequency bands. (Note that the dC(V_{ctrl})/dV_{ctrl} term is only a function of the engaged variable capacitors since the derivative of the constant engaged fixed capacitors is zero. However, the first term, 1/[C(V_{ctrl})^{3/2}], is a function of both the engaged fixed and variable capacitors.)

It should be appreciated that different capacitor and/or inductor configurations may be implemented to attain reasonably constant K_{VCO}, along with desired design parameters, as taught herein. In the depicted embodiment, each selectable capacitor group comprises two fixed capacitors, in series with each other, with the different selectable groups in parallel with each other, as well as with the inductors. However, persons of skill will appreciate that there are numerous other ways to achieve an LC-type VCO and retain reasonably constant Kvco as taught herein. One or more fixed and/or variable capacitors could be used in each group, and the groups could be arranged in different combinations relative to one another other than simply being in parallel, although since capacitors in parallel are additive, it makes maintaining the product of 1/[C(V_{ctrl})^{3/2}] and dC(V_{ctrl})/dV_{ctrl} simpler to implement. Along these lines, the fixed and variable capacitors may be separately controllable, i.e., not all controlled by selection lines Aᵢ. Moreover, their values may be distributed in any suitable manner. for example, the fixed capacitors may be binary weighted, while the variable capacitors could be thermo-coded. the opposite could be true or both could be weighted the same, e.g., binary or thermo-coded.

FIG. 3 shows a circuit for implementing a selectable capacitor group in accordance with some embodiments. It comprises variable capacitors VC_{B}, VC_{C}, switch transistors N1, N2, N3 and fixed capacitors C_{B} and C_{C}, all coupled together as shown. The variable capacitors, VC_{B} and VC_{C}, are formed from PMOS transistors with their drains and sources coupled together, as shown. They are coupled together in a back-to-back configuration, thereby allowing them to be biased by the frequency control voltage V_{ctrl} which is substantially decoupled from the output rails Vₒᵤₜ, V#ₒᵤₜ. With such variable capacitor implementations, as Vctrl increases, so to does the variable capacitance thereby lowering the output frequency.

The selectable capacitor group is coupled between terminals B and C, which correspond to the output rails Vₒᵤₜ and V#ₒᵤₜ from the VCO of FIG. 2. A select control input Aᵢ is coupled to the gates of switch transistors N1, N2, N3, and the frequency control voltage node Vctrl is coupled to the drain/sources of P-type MOS transistors used to form the variable capacitors VC_{B} and VC_{C}. (Note that in this implementation, there are two N-type switches, N1 and N2, to isolate the MOS-implemented variable capacitors from the control voltage (V_{ctrl}), as well as from the output rails. This may be desirable since the control voltage node, which may substantially be DC in nature, may function as an AC ground. In other embodiments, for example, with other types of variable capacitor implementations, this may or may not be desired. Moreover, while MOS-transistor variable capacitors are shown, any suitable variable capacitor solution (e.g., PN junction, etc.) could be used, depending on design objectives.)

(The term “PMOS transistor” refers to a P-type metal oxide semiconductor field effect transistor. Likewise, “NMOS transistor” refers to an N-type metal oxide semiconductor field effect transistor. It should be appreciated that whenever the terms: “transistor”, “MOS transistor”, “NMOS transistor”, or “PMOS transistor” are used, unless otherwise expressly indicated or dictated by the nature of their use, they are being used in an exemplary manner. They encompass the different varieties of MOS devices including devices with different VTs and oxide thicknesses to mention just a few. Moreover, unless specifically referred to as MOS or the like, the term transistor may include other suitable transistor types, e.g., junction-field-effect transistors, bipolar-junction transistors, and various types of three dimensional transistors, known today or not yet developed.)

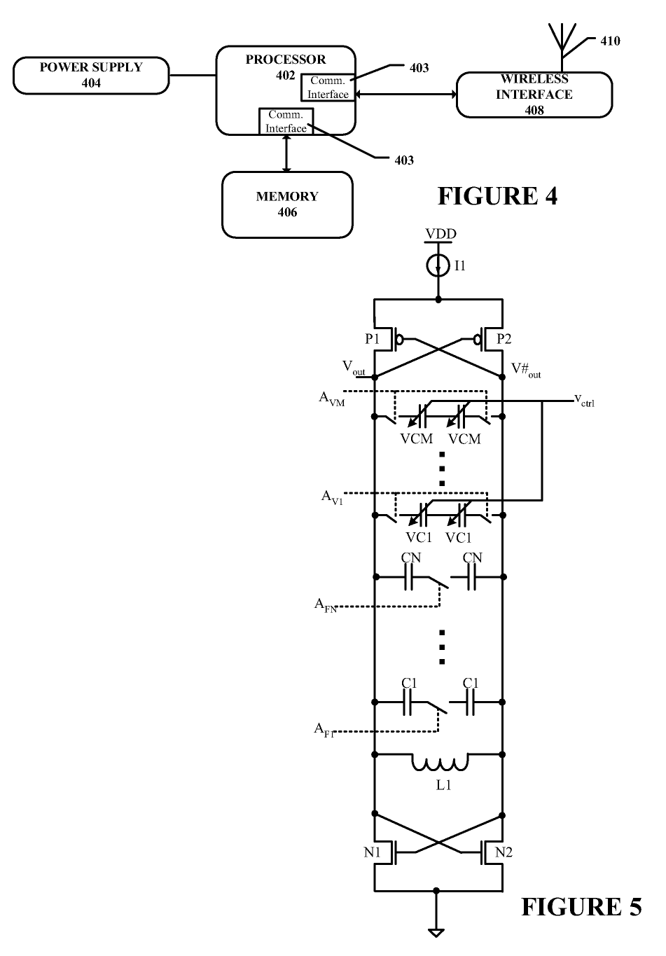

With reference to FIG. 4, one example of a computer system is shown. The depicted system generally comprises a processor 402 that is coupled to a power supply 404, a wireless interface 408, and memory 406. It is coupled to the power supply 404 to receive from it power when in operation. The wireless interface 408 is coupled to an antenna 410 to communicatively link the processor through the wireless interface chip 408 to a wireless network (not shown). The processor 402 comprises a communications interface 403, having one or more LC-type VCOs 403 such as are disclosed herein, to communicatively link the processor 402 to the memory 406.

It should be noted that the depicted computer system could be implemented in different forms. That is, it could be implemented in a single chip module, a circuit board, or a chassis having multiple circuit boards. Similarly, it could constitute one or more complete computers or alternatively, it could constitute a component useful within a computing system.

The invention is not limited to the embodiments described, but can be practiced with modification and alteration within the spirit and scope of the appended claims. For example, FIG. 5 shows another embodiment of an LC-type VCO in accordance with embodiments of the invention. It generally comprises variable capacitor groups, formed from variable capacitors, VC1 to VCM and controlled by control lines A_{V1}, to A_{VM}, and fixed capacitor groups formed from fixed capacitors C1 to CN and separately controlled by control lines A_{FI} to A_{FN}. Thus, it is shown that the fixed and variable capacitors may be controlled in any suitable manner, either in association with each other or independently. This embodiment also employs cross-coupled NMOS transistors N1, 2 and a single inductor L1 coupled between the output rails as shown.

In addition, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

Moreover, it should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A chip, comprising:
an LC-;type VCO having two or more operational frequency bands with substantially equivalent frequency gains.

2. The chip of claim 1, in which the VCO comprises one or more selectable capacitor groups each having at least one fixed capacitor and at least one variable capacitor to be controlled by a frequency control voltage.

3. The chip of claim 2, in which the one or more selectable capacitor groups comprise a plurality of selectable capacitor groups that are controllably coupled in parallel with one another.

4. The chip of claim 3, in which the plurality of selectable capacitor groups are controllably coupled to one or more inductors to form a resonant tank circuit.

5. The chip of claim 2, in which the at least one variable capacitor comprises a MOS transistor configured into a capacitor.

6. The chip of claim 5, in which the at least one variable capacitor comprises first and second MOS capacitors configured as capacitors and coupled together in a back-to-back configuration at a common frequency control voltage node.

7. The chip of claim 2, in which the VCO comprises one or more variable capacitors coupled in parallel to the one or more selectable capacitor groups and to be controlled by the frequency control voltage.

8. The chip of claim 7, in which the product of 1/[C(V_{ctrl})^{3/2}] and dC(V_{ctrl})/dV_{ctrl}, where Vctrl is the frequency control voltage and C(V_{ctrl}) is the total engaged capacitance as a function of the frequency control voltage, is maintained substantially constant for the two or more operational frequency bands.

9. An integrated circuit, comprising:
an amplifier to generate a frequency signal based on a resonant tank circuit that comprises a plurality of selectable fixed and variable capacitors to provide two or more operational bands each having a reasonably equivalent frequency vs. control voltage slope.

10. The integrated circuit of claim 9, in which the amplifier is a differential amplifier having complementary output nodes to provide the frequency signal.

11. The integrated circuit of claim 10, in which the plurality of fixed and variable capacitors make up selectable capacitor groups selectably coupled in parallel with each other and to the complementary output nodes.

12. The integrated circuit of claim 11, in which the tank circuit comprises first and second inductors coupled between the complementary output nodes and a supply reference.

13. The integrated circuit of claim 12, in which the variable capacitors are formed from capacitor-configured MOS transistors.

14. The integrated circuit of claim 13, comprising a variable capacitor fixedly coupled between the complementary output nodes.

15. A computer system, comprising:
a processor having one or more LC-type VCOs to implement at least one communication interface, the one or more LC-type VCOs comprising: two or more operational frequency bands with substantially equivalent frequency gains;
a network interface device coupled to the processor via the at least one communication interface; and
an antenna coupled to the network interface device to communicatively link the processor to a wireless network.

16. The computer system of claim 15, in which the VCO comprises one or more selectable capacitor groups each having at least one fixed capacitor and at least one variable capacitor to be controlled by a frequency control voltage.

17. The computer system of claim 16, in which the one or more selectable capacitor groups comprise a plurality of selectable capacitor groups that are controllably coupled in parallel with one another.

18. The computer system of claim 17, in which the plurality of selectable capacitor groups are controllably coupled to one or more inductors to form a resonant tank circuit.

19. The computer system of claim 16 in which the at least one variable capacitor comprises a MOS transistor configured into a capacitor.

20. The computer system of claim 19, in which the at least one variable capacitor comprises first and second MOS capacitors coupled together in a back-to-back configuration at a common frequency control voltage node.

21. The chip of claim 16, in which the VCO comprises one or more variable capacitors coupled in parallel to the one or more selectable capacitor groups and to be controlled by the frequency control voltage.
